(19) United States
(12) Patent Application Publication
(10) Pub. No.: US 2012/0327606 A1
(43) Pub. Date: Dec. 27, 2012

(54) WIRE CLIP AND HEAT SINK ASSEMBLY USING THE SAME

(75) Inventor: XIAN-XIU TANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/221,884

(22) Filed: Aug. 30, 2011

(30) Foreign Application Priority Data
Jun. 23, 2011 (CN) 201110170612.1

(51) Int. Cl. H05K 7/20; F16M 13/02

(52) U.S. Cl. 361/720; 248/231.81

(57) ABSTRACT

A heat sink clip for fastening a heat sink on a printed circuit board (PCB) includes a wire clip and two hooks. The wire clip can be deformed in assembly to make the hooks extend through two locking slots of the PCB to lock to a second side of the PCB, the clip functions as a lever, a clip, and a latch.

### BACKGROUND

1. Technical Field

The present disclosure relates to clips and, particularly, to a heat sink clip.

2. Description of Related Art

Heat sink clips are widely used to fasten a heat sink to a chip. However, many heat sink clips have a complicated structure and are inconvenient to operate. Therefore, it is desirable to provide a better heat sink clip.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is an isometric view of a heat sink clip, a printed circuit board (PCB), and a heat sink assembled together, according to an embodiment.

FIG. 2 is an exploded, isometric view of FIG. 1.

FIG. 3 is a side view of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

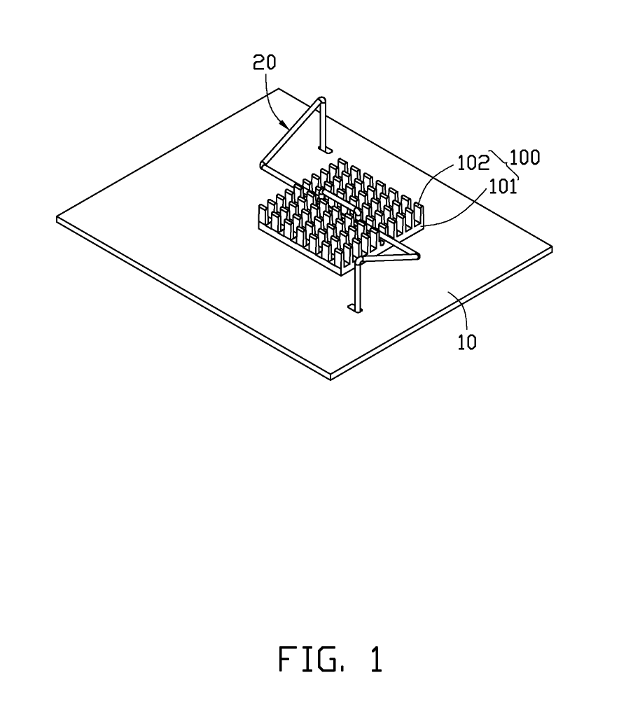

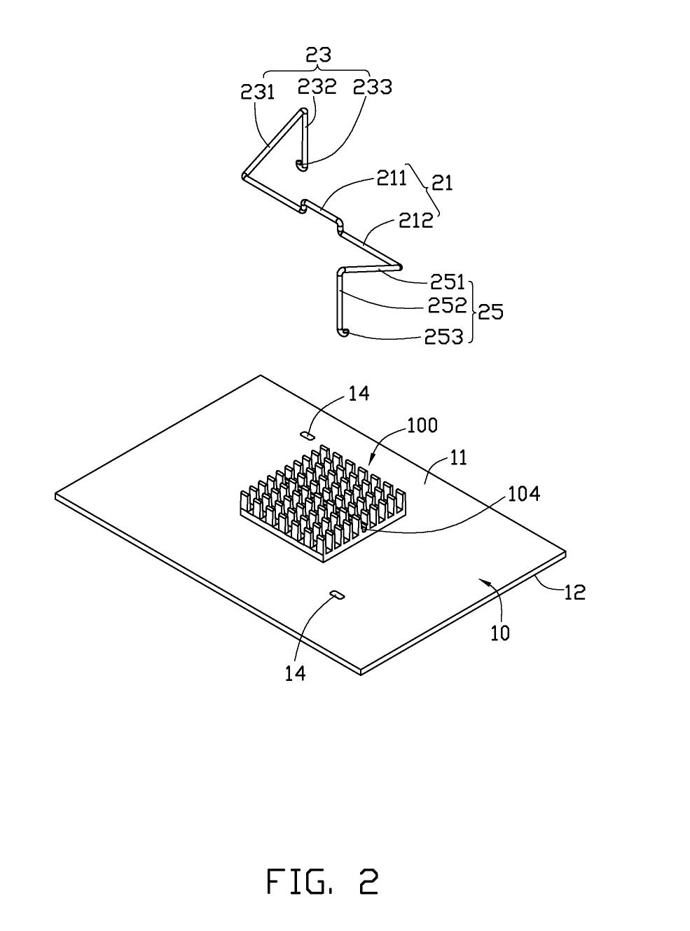

Referring to FIGS. 1-2, a heat sink clip 20, according to an embodiment, is configured for fastening a heat sink 100 to a printed circuit board (PCB) 10.

The PCB 10 includes a first side surface 11, and a second side surface 12 opposite to the first side surface 11. An electronic component (not shown) is fixed on the first side surface 11 of the PCB 10. The heat sink 100 is set on the electronic component. The PCB 10 defines two elongated locking slots 14 adjacent to opposite sides of the heat sink 100. In this embodiment, the locking slots 14 are located on a diagonal line across the heat sink 100.

The heat sink 100 includes a heat-transferring base 101 and a plurality of fins 102 extending up from a surface of the heat-transferring base 101 resting on the PCB 10 or the electronic component. A channel 104 is defined in the top surface of the heat-transferring base 101 and between the fins 102.

The heat sink clip 20 is made by bending a resilient metal wire, and the clip 20 functions as a lever, a spring, and a latch. The heat sink clip 20 includes a pressing portion 21, a first locking portion 23 extending from a first end of the pressing portion 21, and a second locking portion 25 extending from the other end of the pressing portion 21 away from the first locking portion 23. The pressing portion 21 includes a substantially “n”-shaped main wire 211 and two pressing wires 212 horizontally extending from opposite ends of the main wire 211. The first locking portion 23 includes a resilient first connecting wire 231 slanting back and up from the distal end of one of the pressing wires 212, a resilient first locking wire 232 extending down from the distal end of the first connecting wire 231 opposite to the pressing wire 212, and a U-shaped first hook 233 formed from the distal end of the first locking wire 232 opposite to the first connecting wire 231. The second locking portion 25 includes a resilient second connecting wire 251 slanting forward and up from the distal end of the other pressing wire 212, a resilient second locking wire 252 extending down from the distal end of the second connecting wire 251 opposite to the pressing wire 212, and a U-shaped second hook 253 formed from the distal end of the second locking wire 252.

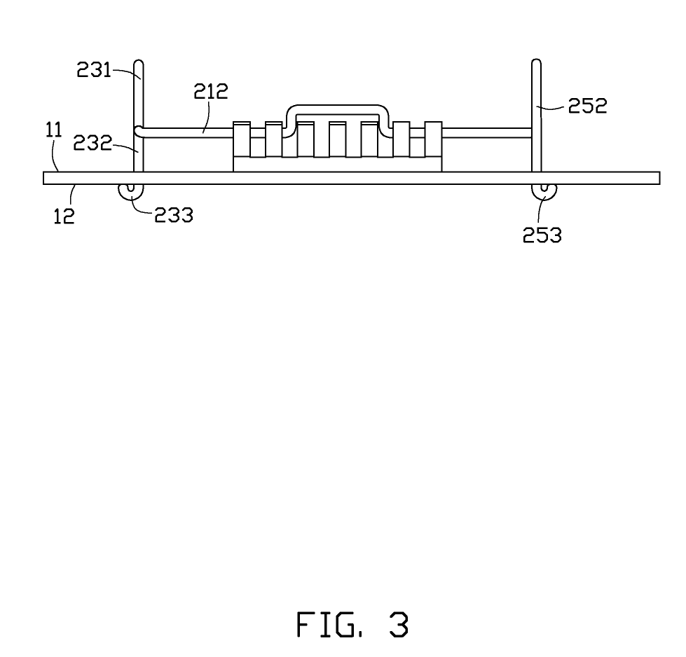

Referring to FIG. 3, in assembly, the pressing wires 212 are received in the channel 104. The first locking portion 23 and the second locking portion 25 are slightly deformed, toward each other. The first hook 233 and the second hook 253 are inserted into the corresponding locking slots 14, and the first locking portion 23 and the second locking portion 25 are released. The first connecting wire 231 and the first locking wire 232 are released to make the first hook 233 lock to the second side surface 12 of the PCB 10. The second connecting wire 251 and the second locking wire 252 are released to make the second hook 253 lock to the second side surface 12 of the PCB 10.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A heat sink clip for securing a heat sink on a printed circuit board (PCB), the heat sink comprising a heat-transferring base mounted to a first side of the PCB and a plurality of fins extending up from a surface of the heat-transferring base opposite to the PCB, the PCB defining two locking slots at two opposite sides of the heat sink, the heat sink clip comprising:
a pressing portion for pressing on the surface of the heat-transferring base;
a first locking portion extending from a first end of the pressing portion, wherein the first locking portion comprises a resilient first connecting wire slanting back and up from the first end of the pressing portion, a resilient first locking wire extending down from a distal end of the first connecting wire opposite to the pressing portion, and a first hook formed from a distal end of the first locking wire opposite to the first connecting wire; and
a second locking portion slanting from a second end of the pressing portion, wherein the second locking portion comprises a resilient second connecting wire slanting forward and up from the second end of the pressing portion, a resilient second locking wire extending down from a distal end of the second connecting wire opposite to the pressing portion, and a second hook formed from a distal end of the second locking wire opposite to the second connecting wire;
wherein the first locking portion and the second locking portion are operable to be pressed to deform toward each other, the first hook and the second hook are inserted into the locking slots, respectively, and when the first locking portion and the second locking portion are released, the first connecting wire and the first locking wire are released to make the first hook lock to a second side of the PCB opposite to the first side, the second connecting wire and the second locking wire are released to make the second hook lock to the second side of the PCB.

2. The heat sink clip of claim 1, wherein the pressing portion comprises a substantially “n”-shaped main wire and two pressing wires horizontally extending from opposite ends of the main wire for pressing the heat sink, the first and second connecting wires extend from distal ends of the pressing wires opposite to the main wire, respectively.

3. The heat sink clip of claim 2, wherein the pressing wires are operable to pass through a channel defined between the fins of the heat-transferring base.

4. The heat sink clip of claim 1, wherein the heat sink clip is made by bending a resilient metal wire.

5. The heat sink clip of claim 1, wherein the first hook and the second hook are substantially U-shaped.

6. An assembly comprising:
a printed circuit board (PCB) defining two locking slots;
a heat sink set on the PCB and located between the locking slots, the heat sink comprising a heat-transferring base facing a first side of the PCB and a plurality of fins extending up from a surface of the heat-transferring base opposite to the PCB; and
a heat sink clip comprising:
a pressing portion for pressing the surface of the heat-transferring base;
a first locking portion extending from a first end of the pressing portion, wherein the first locking portion comprises a resilient first connecting wire slanting back and up from the first end of the pressing portion, a resilient first locking wire extending down from a distal end of the first connecting wire opposite to the pressing portion, and a first hook formed from a distal end of the first locking wire opposite to the first connecting wire; and
a second locking portion extending forward from a second end of the pressing portion, wherein the second locking portion comprises a resilient second connecting wire slanting forward and up from the second end of the pressing portion, a resilient second locking wire extending down from a distal end of the second connecting wire opposite to the pressing portion, and a second hook formed from a distal end of the second locking wire opposite to the second connecting wire;
wherein the first locking portion and the second locking portion are pressed to deform toward each other, the first hook and the second hook extend through the locking slots, respectively, and when the first locking portion and the second locking portion are released, the first connecting wire and the first locking wire are released to make the first hook lock to a second side of the PCB, the second connecting wire and the second locking wire are released to make the second hook lock to the second side of the PCB.

7. The assembly of claim 6, wherein the pressing portion comprises a substantially “n”-shaped main wire and two pressing wires horizontally extending from opposite ends of the main wire for pressing the heat sink, the first and second connecting wires extend from distal ends of the pressing wires, respectively.

8. The assembly of claim 7, wherein the pressing wires are operable to pass through a channel defined between the fins of the heat-transferring base.

9. The assembly of claim 6, wherein the heat sink clip is made by bending a resilient metal wire.

10. The assembly of claim 6, wherein the first hook and the second hook are substantially U-shaped.

11. The assembly of claim 6, wherein the locking slots are located in an extension line of a diagonal of the heat sink.
